(19) United States
(12) Patent Application Publication
(10) Pub. No.: US 2026/0123460 A1
(43) Pub. Date: Apr. 30, 2026

(54) POWER MODULE PACKAGE

(71) Applicant: Monolithic Power Systems, Inc., Kirkland, WA (US)

(72) Inventors: Kwang-Soo Kim, Sunnyvale, CA (US); Di Han, San Jose, CA (US)

(21) Appl. No.: 18/933,407

(22) Filed: Oct. 31, 2024

(51) Int. Cl. H01L 23/495; H01L 23/00; H01L 25/16

(52) U.S. Cl. CPC H10W 70/481; H10W 70/411; H10W 70/442; H10W 90/00; H10W 72/07552; H10W 72/527; H10W 72/5363; H10W 72/5445; H10W 90/753; H10W 90/754

(57) ABSTRACT

A power module is provided. The power module includes a first lead frame, a first die, a substrate, a second lead frame, and a second die. The first lead frame has a first part and a second part. The first die is arranged on top of the first part of the first lead frame. A first power device is formed on the first die. The substrate is arranged on top of the second part of the first lead frame. The second lead frame is arranged on top of the substrate. The second die is arranged on top of the second lead frame. A first control circuit is formed on the second die, and the first control circuit is configured to control the first power device.

### TECHNICAL FIELD

The present disclosure relates generally to electronic circuits package, and more particularly but not exclusively to power module package.

### BACKGROUND OF THE INVENTION

Power modules are employed to provide one or more voltages to various electronic devices. A power module may integrate power integrated circuits (ICs), control ICs, passive devices, etc. Furthermore, to improve integration, the size of the power module needs to be small. In high-voltage applications, high voltages also bring challenges to thermal performance and package of the power module. Therefore, it is desirable to provide a cost-effective power module with high-power density, high-efficiency, and excellent heat dissipation capability in space-constrained environments.

### SUMMARY OF THE INVENTION

According to an embodiment of the present disclosure, a power module is provided. The power module includes a first lead frame, a first die, a substrate, a second lead frame, and a second die. The first lead frame has a first part and a second part. The first die is arranged on top of the first part of the first lead frame. A first power device is formed on the first die. The substrate is arranged on top of the second part of the first lead frame. The second lead frame is arranged on top of the substrate. The second die is arranged on top of the second lead frame. A first control circuit is formed on the second die, and the first control circuit is configured to control the first power device.

According to another embodiment of the present disclosure, a power module is provided. The power module includes a first lead frame, a first die, a second lead frame, a second die, a substrate, and a third lead frame. The first die is arranged on top of the first lead frame. A first power device is formed on the first die. The second lead frame is electrically isolated from the first lead frame. The second die is arranged on top of the second lead frame. A second power device is formed on the second die. The substrate is partially overlapped with the first lead frame, and the substrate is partially overlapped with the second lead frame. The third lead frame is arranged on top of the substrate. A control circuit is formed on the third lead frame, and the control circuit is configured to control the first power device and the second power device.

According to yet another embodiment of the present disclosure, a power module is provided. The power module includes a first lead frame, a first die, a second lead frame, a second die, and a substrate. The first lead frame includes a first exposed pad and a first DAP. The first DAP is arranged on top of the first exposed pad. The first die is arranged on top of the first DAP of the first lead frame. A first power device is formed on the first die. The second lead frame is located adjacent to the first lead frame. The first lead frame and the second lead frame are separated from each other. The second lead frame includes a second exposed pad and a second DAP. The second DAP is arranged on top of the second exposed pad. The second die is arranged on top of the second DAP of the second lead frame. A second power device is formed on the second die. The substrate is arranged on top of a part of the first lead frame and a part of the second lead frame. A distance between the first DAP and the second DAP is smaller than a distance between the first exposed pad and the second exposed pad.

### BRIEF DESCRIPTION OF THE DRAWINGS

The present disclosure can be further understood with reference to following detailed description and appended drawings, wherein like elements are provided with like reference numerals. These drawings are only for illustration purpose, thus may only show part of the devices and are not necessarily drawn to scale.

FIG. 1A is a side view of a power module in accordance with an embodiment of the present disclosure.

FIG. 1B is a top view of the power module as shown in FIG. 1A in accordance with an embodiment of the present disclosure.

FIG. 2 is a top view of a power module in accordance with another embodiment of the present disclosure.

FIG. 3A is a top view of a power module in accordance with another embodiment of the present disclosure.

FIG. 3B is a side view of the power module as shown in FIG. 3A in accordance with an embodiment of the present disclosure.

FIG. 3C is a bottom view of the power module as shown in FIG. 3A in accordance with an embodiment of the present disclosure.

FIG. 4 is a top view of a power module in accordance with yet another embodiment of the present disclosure.

FIG. 5 is a top view of a power module in accordance with yet another embodiment of the present disclosure.

FIG. 6 is a schematic diagram of a switching circuit in accordance with an embodiment of the present disclosure.

FIGS. 7A-7F are schematic diagrams of an assembly process of the power module in accordance with an embodiment of the present disclosure.

The use of the same reference label in different drawings indicates the same or like components.

### DETAILED DESCRIPTION

Various embodiments of the present disclosure will now be described. In the following description, some specific details, such as example circuits and example values for these circuit components, are included to provide a thorough understanding of embodiments. One skilled in the relevant art will recognize, however, that the present disclosure can be practiced without one or more specific details, or with other methods, components, materials, etc. In other instances, well-known structures, materials, processes or operations are not shown or described in detail to avoid obscuring aspects of the present disclosure.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used include both combinations and sub-combinations of various features described herein as well as variations and modifications thereof. These phrases used herein do not necessarily refer to the same embodiment, although they may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or that the element is indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

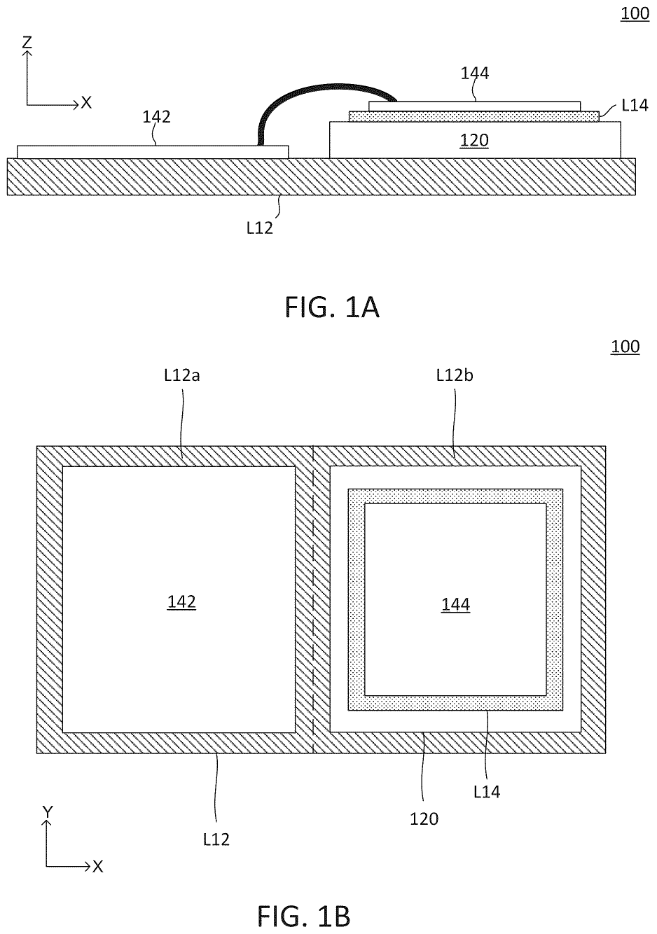

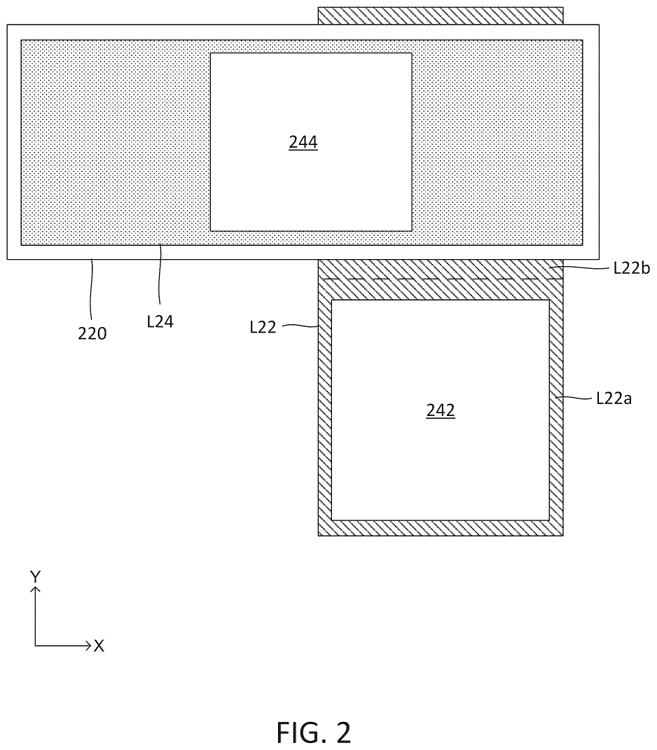

Please refer to FIGS. 1A and 1B. FIG. 1A is a side view of a power module 100 in accordance with an embodiment of the present disclosure. FIG. 1B is a top view of the power module 100 as shown in FIG. 1A in accordance with an embodiment of the present disclosure. The power module 100 includes a lead frame L12, a die 142, a substrate 120, a lead frame L14, and a die 144. In some embodiments, the lead frames L12 and L14 are configured to support the dies 142 and 144, respectively. After the packaging of the power module 100, at least a portion of the lead frame L12 is exposed from a molding compound and is configured as the pin(s) of the power module 100. The lead frame L12 has a first part L12a and a second part L12b. The die 142 is arranged on top of the first part L12a of the lead frame L12. A power device is formed on the die 142. The substrate 120 is arranged on top of the second part L12b of the lead frame L12. The lead frame L14 is arranged on top of the substrate 120. The die 144 is arranged on top of the lead frame L14. A control circuit is formed on the die 144, and the control circuit is configured to control the power device formed on the die 142.

In some embodiments, each of the lead frames L12 and L14 includes copper, copper-alloy, iron-nickel alloy, etc. In some embodiments, the substrate 120 may be a printed circuit board (PCB), a direct bonded copper (DBC) substrate, a direct plated copper (DPC) substrate, a ceramic substrate, etc.

In some embodiments, the power device includes at least one power switch. The power switch may include, but not limited to, a bipolar transistor (BJT), a field-effect transistor (FET), an insulated-gate bipolar transistor (IGBT), a MOSFET, a HEMT, a JFET, a Gate Turn-off Thyristor (GTO), or a Gate-Commutated Thyristor (GCT). The power device is formed on the die 142. In one embodiment, the die 142 is a silicon (Si) die. In another embodiment, the die 142 is a silicon carbide (SiC) die. In yet another embodiment, the die 142 is a gallium nitride (GaN) die. However, the present disclosure is not limited thereto. In some embodiments, the power switch is a wide-bandgap (WBG) semiconductor switch formed on WBG semiconductor die. In one embodiment, the control circuit formed on the die 144 is a gate driver configured to provide a driving signal to the gate terminal of the transistor. In alternative embodiments, the control circuit formed on the die 144 is a controller for the one or more power switches.

In some embodiments, the power module 100 further includes molding compounds (not shown in FIGS. 1A and 1B), and the dies 142 and 144 are encapsulated by the molding compounds. The molding compounds provide electrical isolation between the components in the power module 100.

Please refer to FIGS. 1A and 1B. In some embodiments, the power device formed on the die 142 generates heat during operation, and the lead frame L12 connected to the die 142 is configured to dissipate the heat. As shown in FIGS. 1A and 1B, the lead frame L12 is extended to and arranged below the substrate 120. Alternatively speaking, in addition to the portion below the die 142, the lead frame L12 also has an extended portion below the substrate 120. Accordingly, the lead frame L12 has a large area for dissipating the heat generated by the power device on the die 142. Thus, the power module in the present disclosure with extended lead frame may provide better heat dissipation.

It should be noted that the structure of the power module 100 is merely exemplary and does not limit the present disclosure. For example, the lead frame L12 may have shape other than the rectangle as shown in FIGS. 1A and 1B. The lead frame L12 may improve the heat dissipation of the power module as long as it has an extended portion below the substrate 120.

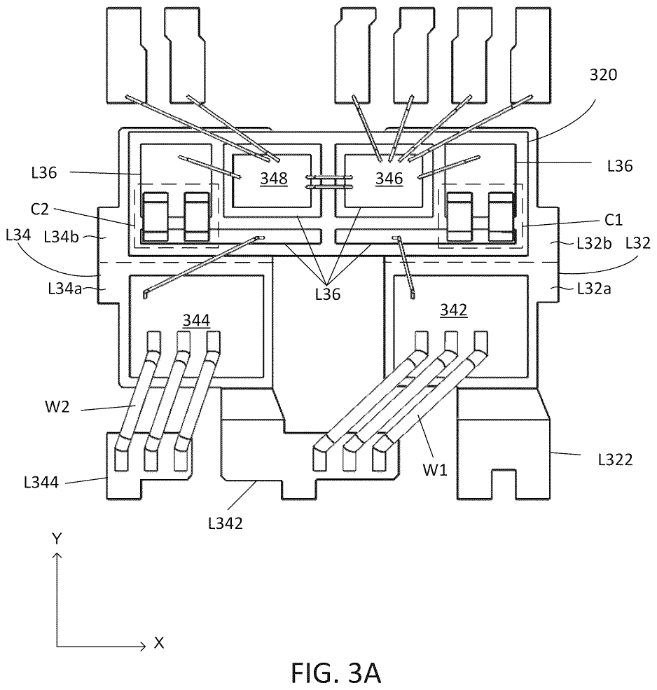

FIG. 2 is a top view of a power module 200 in accordance with another embodiment of the present disclosure. The power module 200 includes a lead frame L22, a die 242, a substrate 220, a lead frame L24, and a die 244. The lead frame L22 has a first part L22a and a second part L22b. The die 242 is arranged on top of the first part L22a of the lead frame L22. The substrate 220 is arranged on top of the second part L22b of the lead frame L22. The lead frame L24 is arranged on top of the substrate 220. The die 244 is arranged on top of the lead frame L24. In this embodiment, the substrate 220 is partially overlapped with the lead frame L22. Since the lead frame L22 has an extended portion below the substrate 220, the power module 200 may provide better heat dissipation. It should be noted that the arrangement of the lead frames and the substrate described above is merely exemplary, and the present disclosure does not limit thereto. Persons having ordinary skills in the art may adjust the size, arrangement, and location of the lead frames and the substrate according to actual needs.

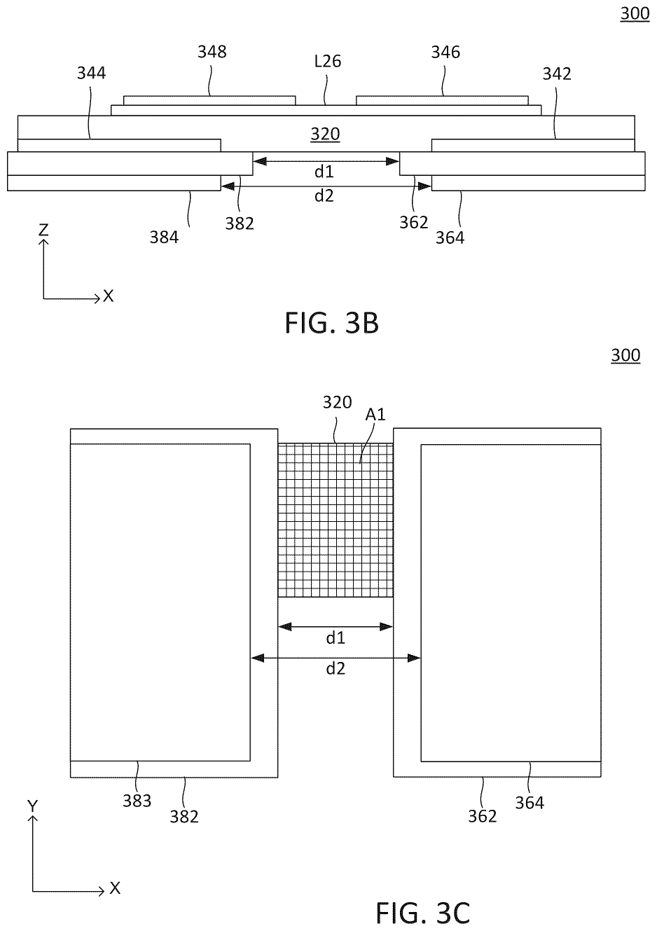

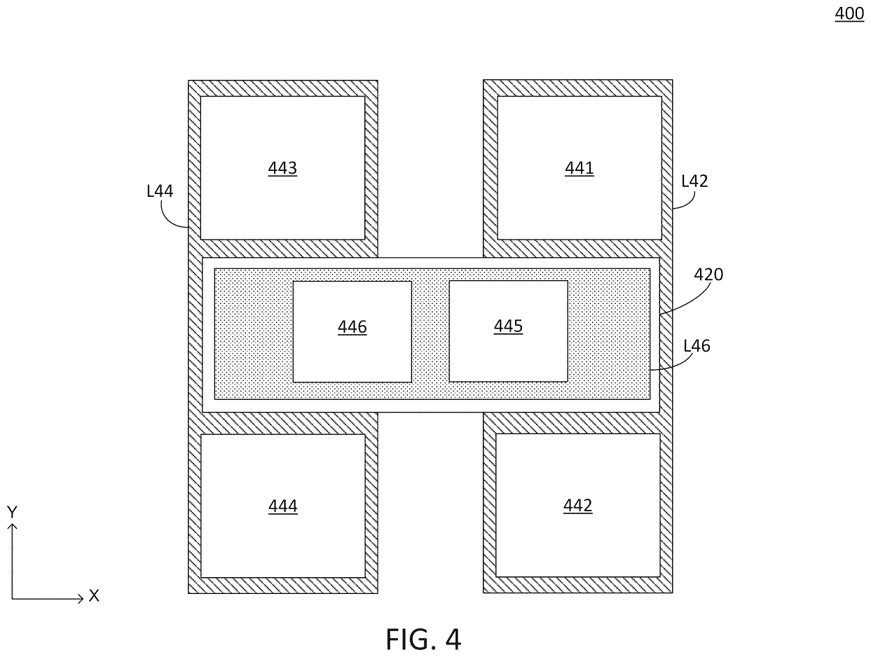

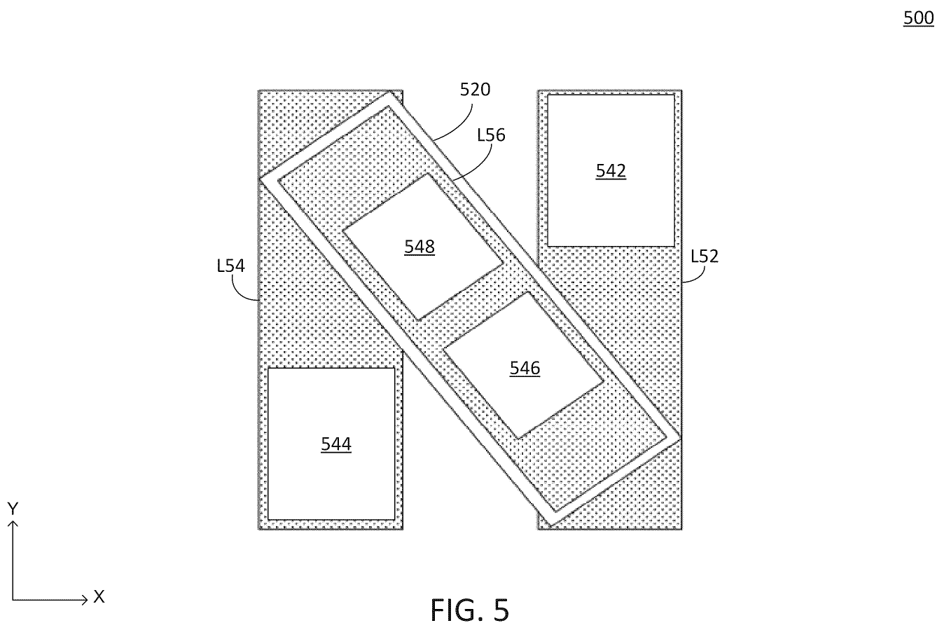

In some embodiments, the power module may include two power devices. Please refer to FIG. 3A. FIG. 3A is a top view of a power module 300 in accordance with another embodiment of the present disclosure. The power module 300 includes lead frames L32 and L34, a substrate 320, a lead frame L36, and dies 342, 344, 346, and 348. The first power device is formed on the die 342. The second power device is formed on the die 344. Accordingly, the lead frames L32 and L34 are adjacent but separate from each other. Similar to the lead frame L12 as shown in FIG. 1A, each of the lead frames L32 and L34 includes first and second parts. The lead frame L32 includes the first part L32a and the second part L32b, and the lead frame L34 includes the first part L34a and the second part L34b. Both the die 342 and the die 344 are arranged on the same side of the respective lead frames L32 and L34, i.e., the first part L32a of the lead frame L32, and the first part L34a of the lead frame L34. The substrate 320 is arranged on the other side (i.e., the second part) of both lead frames L32 and L34. Alternatively speaking, the substrate 320 is arranged on top of the lead frames L32 and L34 and is partially overlapped with the lead frame L32 and partially overlapped with the lead frame L34. The lead frame L36 is arranged on top of the substrate 320, and the dies 346 and 348 are arranged on top of the lead frame L36. The control circuit could be arranged on the substrate 320. In some embodiments, two power switches are formed on the dies 342 and 344, respectively. In one embodiment, two control circuits are formed on the dies 346 and 348, respectively, and the two control circuits are configured to control the two power switches. In alternative embodiments, the power module includes one control circuit configured to control the two power switches, and the control circuit is formed on a die arranged on the substrate 320.

In some embodiments, the power module 300 further includes electronic components that are arranged on the substrate 320 and are configured to couple to the power devices or the control circuits. For example, electronic components C1 are coupled to the power device formed on the die 342 and/or the control circuit formed on the die 346, and electronic components C2 are configured to couple to the power device formed on the die 344 and/or the control circuit formed on the die 348. In some embodiments, the electronic components C1 and C2 are capacitors, diodes, inductors, and/or other passive components. In some embodiments, the lead frame L36 includes multiple regions arranged on top of the substrate 320, and the dies 346 and 348 and the electronic components C1 and C2 are arranged on the different regions of the lead frame L36.

In some embodiments, the substrate 320 disposed on top of the lead frames L32 and L34 forms a bridge between the lead frames L32 and L34 such that the lead frames L32 and L34 and the substrate 320 together form a U-shaped structure. The lead frames L32 and L34 correspond to two parallel arms of the U-shaped structure, and the substrate 320 corresponds to a connection part of the U-shaped structure that connects the two parallel arms.

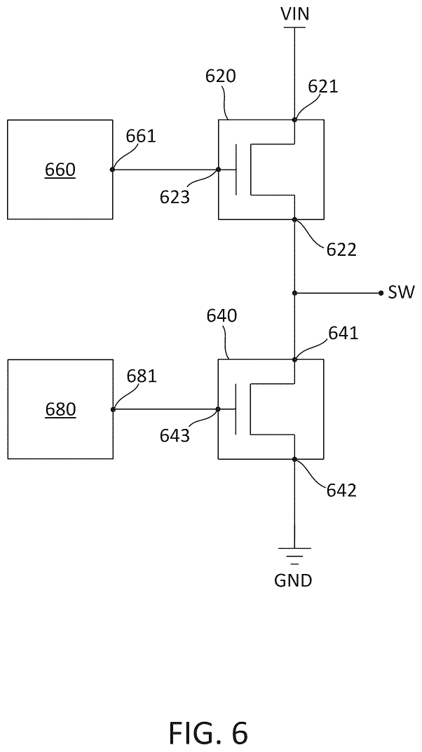

Please refer to FIG. 4. FIG. 4 is a top view of a power module 400 in accordance with yet another embodiment of the present disclosure. The power module 400 includes lead frames L42, L44, and L46, dies 441 442, 443, 444, 445, and 446, and a substrate 420. In the embodiment of FIG. 4, the substrate 420 disposed on top of the lead frames L42 and L44 forms a bridge between the lead frames L42 and L44 such that the lead frames L42 and L44 and the substrate 420 together form an H-shaped structure.

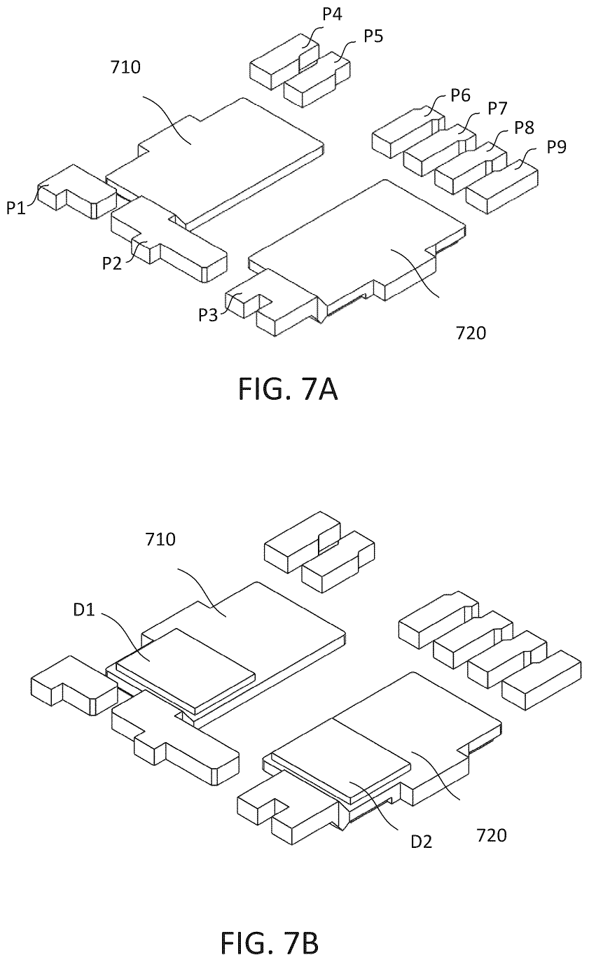

Please refer to FIG. 5. FIG. 5 is a top view of a power module 500 in accordance with yet another embodiment of the present disclosure. The power module 500 includes lead frames L52, L54, and L56, dies 542, 544, 546, and 548, and a substrate 520. In the embodiment of FIG. 5, the substrate 520 disposed on top of the lead frames L52 and L54 forms a bridge between the lead frames L52 and L54 such that the lead frames L52 and L54 and the substrate 520 together form an N-shaped structure.

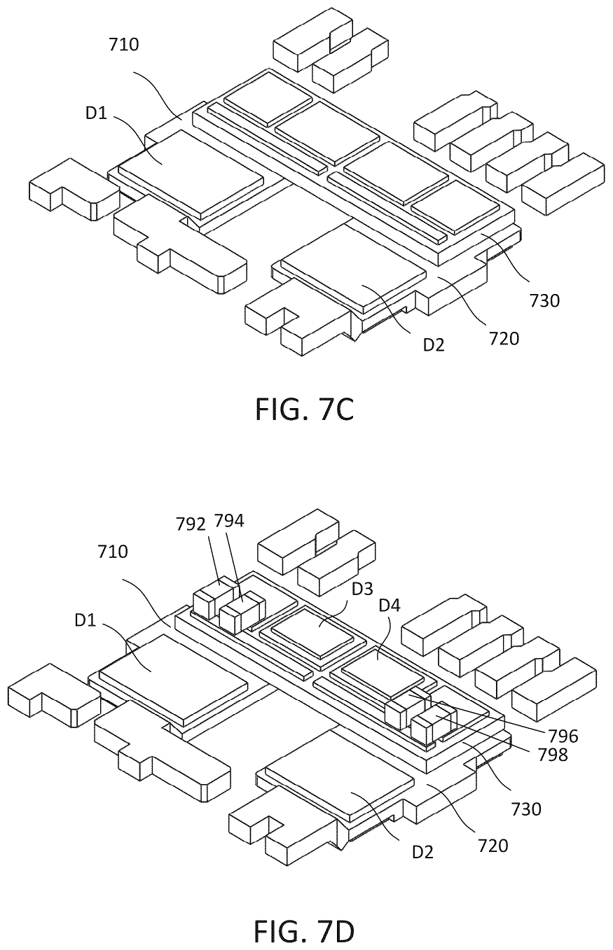

In some embodiments, the power module 300 as shown in FIG. 3A is a switching circuit that includes two power devices and two control circuits and is configured to provide a switching voltage. For example, the power module 300 is the switching circuit 600 as shown in FIG. 6. Please refer to FIG. 3A and FIG. 6. FIG. 6 is a schematic diagram of a switching circuit 600 in accordance with an embodiment of the present disclosure. The switching circuit 600 includes power devices 620 and 640 coupled in series between a first voltage (e.g., the input voltage VIN) and a second voltage (e.g., the ground voltage GND), and the switching circuit 600 is configured to provide a switching voltage SW. For instance, the power device 620 has a first terminal 621 configured to receive the input voltage VIN, a second terminal 622, and a control terminal 623 configured to receive a control signal from a terminal 661 of the control circuit 660. The power device 640 has a first terminal 641 coupled to the second terminal 622 of the power device 620, a second terminal 642 configured to receive a ground voltage GND, and a control terminal 643 configured to receive a control signal from a terminal 681 of the control circuit 680. Accordingly, the power devices 620 and 640 are coupled in series between the input voltage VIN and the ground voltage GND and are configured to provide the switching voltage SW based on the control signals provided by the control circuits 660 and 680. In one implementation, the power device 620 is formed on the die 342, the power device 640 is formed on the die 344, the control circuit 660 is formed on the die 346, and the control circuit 680 is formed on the die 348.

Please still refer to FIG. 3A and FIG. 6. In some embodiments, the lead frame L32 further includes a pad L322. The pad L322 is configured to receive the input voltage VIN. In some embodiments, the lead frame L34 further includes a pad L342 and a pad L344. The pad L342 is configured to provide the switching voltage SW, and the pad L344 is configured to receive the ground voltage GND. The die 342 is coupled to the pad L342 of the lead frame L34 through a bonding wire W1, and the die 344 is coupled to the pad L344 of the lead frame L34 through a bonding wire W2. In some embodiments, as shown in FIG. 3A, the pad L342 of the lead frame L34 is located between the pad L322 of the lead frame L32 and the pad L344 of the lead frame L34.

In some embodiments, the power circuit 600 as shown in FIG. 6 is used in a high-voltage application, and the voltage difference between the input voltage VIN and the switching voltage SW is large. Accordingly, for the safe operation of the power module 300, the lead frame L32 receiving the input voltage VIN and the lead frame L34 providing the switching voltage L34 are separated by a safety distance and are electrically isolated from each other, as shown in FIG. 3A. However, the distance leaves an empty area between the lead frames L32 and L34. To utilize this area, the present disclosure provides the bridge-type substrate 320 arranged on the lead frames L32 and L34, so that more components (e.g., the control circuits formed on the dies 346 and 348) may be integrated in the power module.

Please refer to FIGS. 3A-3C. FIG. 3B is a side view of the power module 300 as shown in FIG. 3A in accordance with an embodiment of the present disclosure. FIG. 3C is a bottom view of the power module 300 as shown in FIG. 3A in accordance with an embodiment of the present disclosure. For the purpose of illustration, the pads L322, L342, and L344 as shown in FIG. 3A are omitted in FIGS. 3B and 3C. In some embodiments, as shown in FIGS. 3B and 3C, the lead frame L32 includes a die attach pad (DAP) 362 and an exposed pad 364. The DAP 362 is arranged on top of the exposed pad 364. The DAP 362 is configured to connect to the die 342 and is extended to and arranged below the substrate 320. Similar to the lead frame L32, the lead frame L34 includes a DAP 382 and an exposed pad 384. The DAP 382 is arranged on top of the exposed pad 384. The DAP 382 is configured to connect the die 344 and is extended to and arranged below the substrate 320. In some embodiments, after the power module 300 is encapsulated by the molding compounds, and the bottom surface of the exposed pad 364 and the bottom surface of the exposed pad 384 are not covered by the molding compounds and are configured to connect to a motherboard to transmit electrical signals. For example, the exposed pad 364 is configured to receive the input voltage, and the exposed pad 384 is configured to provide the switching voltage.

In some embodiments, the DAP 362 and the DAP 382 are separated by a distance d1, the exposed pad 364 and the exposed pad 384 are separated by a distance d2, and the distance d1 is smaller than the distance d2. Alternatively speaking, the distance d1 between the DAP 362 and the DAP 382 is smaller than the distance d2 between the exposed pad 364 and the exposed pad 384. In some embodiments, the distance d1 is the shortest distance between the DAP 362 and the DAP 382, and the distance d2 is the shortest distance between the exposed pad 364 and the exposed pad 384. Since the distance d1 is smaller than the distance d2, the DAPs 362 and 382 may have large area for heat dissipation, and the exposed pads 364 and 384 may be separated by the larger distance d2 to satisfy the requirement of safety distance. In some embodiments, the safety distance is determined based on the input voltage, the ground voltage, the switching voltage, etc.

As shown in FIG. 3C, an area A1 is on the back of the substrate 320 and is not overlapped with the lead frames L32 and L34. In some embodiments, the power module 300 may further include electronic components that are arranged on area A1 (i.e., the bottom surface of the substrate 320 that is not overlapped with the lead frames L32 and L34), and thus more components may be integrated in the power module.

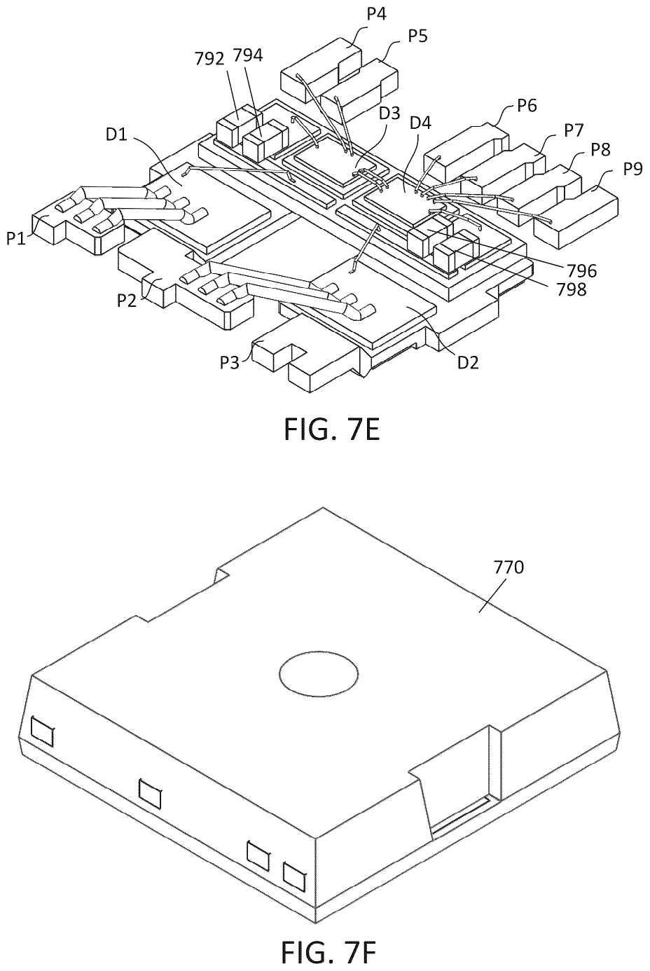

FIGS. 7A-7F are schematic diagrams of an assembly process of the power module in accordance with an embodiment of the present disclosure. The assembly process includes the following actions. As shown in FIG. 7A, the lead frames 710 and 720 are provided. Specifically, the lead frame 710 includes multiple pads P1, P2, and P4-P5. The lead frame 720 includes multiple pads P3, and P6-P9. As shown in FIG. 7B, die attached process is performed. For example, two power devices dies D1 and D2 are attached on the lead frames 710 and 720, respectively. As mentioned before, the die D1/D2 is arranged on top of the first part of the lead frame 710/720. As shown in FIG. 7C, the substrate 730 is attached on the lead frames 710 and 720. Specifically, the substrate 730 is arranged on top of the second part of the lead frames 710 and 720. As shown in FIG. 7D, die and passive component attachment is performed. For instance, two controller IC dies D3 and D4 and the electronic components 792, 794, 796, 798 are attached on the lead frame on the substrate 730. As shown in FIG. 7E, electrical connection processing that couples the semiconductor dies and other components to a circuit is performed. For example, wire bonding process is performed. As shown in FIG. 7E, bond wires are formed on the dies D1-D4 to provide electrical circuit connections for power devices (formed on D1/D2), controller ICs (formed on D3/D4), electronic components 792, 794, 796, 798, other circuitry of the integrated power module, and pads P1-P9. Molding process is performed as shown in FIG. 7F. For example, the molding process includes forming a package structure 770 to encapsulate the power module with the molding compounds by enclosing the semiconductor dies D1-D4, lead frames 710 and 720, substrate 730 and electronic components 792, 794, 796, 798 with an opening for the pads/pins (metal terminals) of the integrated power module. Molding compounds can be epoxy molding compounds (EMC). Moreover, lead trimming and/or forming process is performed.

The present disclosure provides a power module with extended lead frames and bridge-type substrate. Since the extended lead frame has large area, the heat dissipation of the power module is improved. In addition, since the bridge-type substrate arranged on top of the lead frames utilizes the area between the lead frames, more components may be integrated into the power module.

While various embodiments have been described above to illustrate the switch circuit of the present disclosure, it should be understood that they have been presented by way of example only, and not limitation. Rather, the scope of the present disclosure is defined by the following claims and includes combinations and sub-combinations of the various features described above, as well as variations and modifications thereof, which would occur to persons skilled in the art upon reading the foregoing description.

What is claimed is:

1. A power module, comprising:
a first lead frame having a first part and a second part;
a first die arranged on top of the first part of the first lead frame, wherein a first power device is formed on the first die;
a substrate arranged on top of the second part of the first lead frame;
a second lead frame arranged on top of the substrate; and
a second die arranged on top of the second lead frame, wherein a first control circuit is formed on the second die, and the first control circuit is configured to control the first power device.

2. The power module of claim 1, further comprising:
a third lead frame arranged adjacent to the first lead frame, wherein the third lead frame has a first part and a second part, the substrate is arranged on top of the second part of the third lead frame, and the third lead frame is electrically isolated from the first lead frame; and
a third die arranged on top of the first part of the third lead frame, wherein a second power device is formed on the third die;
wherein the first power device has a first terminal, a second terminal, and a control terminal, and the first terminal of the first power device is coupled to a first pad of the first lead frame and is configured to receive a first voltage;
wherein the second power device has a first terminal, a second terminal, and a control terminal, the first terminal of the second power device is coupled to a first pad of the third lead frame, and the second terminal of the second power device is coupled to a second pad of the third lead frame and is configured to receive a second voltage;
wherein the first power device and the second power device are coupled in series between the first voltage and the second voltage.

3. The power module of claim 2, further comprising:
a fourth die arranged on top of the second lead frame, wherein a second control circuit is formed on the fourth die, and the second control circuit is configured to control the second power device.

4. The power module of claim 2, further comprising:
a plurality of electronic components arranged on the substrate and configured to couple to the first power device or the first control circuit.

5. The power module of claim 2, wherein the substrate is disposed on top of the first lead frame and the third lead frame and forms a bridge between the first lead frame and the third lead frame such that the first lead frame, the third lead frame, and the substrate together form a U-shaped structure.

6. The power module of claim 2, wherein the control terminal of the first power device is configured to receive a first control signal, and the control terminal of the second power device is configured to receive a second control signal;
wherein the second terminal of the first power device and the first terminal of the second power device are coupled together via the first pad of the third lead frame, and the first pad of the third lead frame is configured to provide a switching voltage;
wherein the first pad of the third lead frame is located between the first pad of the first lead frame and the second pad of the third lead frame.

7. The power module of claim 2, wherein the first lead frame includes a first die attach pad (DAP) configured to connect the first die, and the first DAP is extended to and arranged below the substrate;
wherein the third lead frame includes a second DAP configured to connect the second die, and the second DAP is extended to and arranged below the substrate;
wherein the first DAP and the second DAP are separated by a first distance.

8. The power module of claim 7, wherein the first lead frame further includes a first exposed pad arranged under the first DAP, and the third lead frame further includes a second exposed pad arranged under the second DAP;
wherein the first exposed pad and the second exposed pad are separated by a second distance, and the first distance is smaller than the second distance.

9. A power module, comprising:
a first lead frame;
a first die arranged on top of the first lead frame, wherein a first power device is formed on the first die;
a second lead frame, wherein the second lead frame is electrically isolated from the first lead frame;
a second die arranged on top of the second lead frame, wherein a second power device is formed on the second die;
a substrate, wherein the substrate is partially overlapped with the first lead frame, and the substrate is partially overlapped with the second lead frame; and
a third lead frame arranged on top of the substrate;
wherein a control circuit is formed on the third lead frame, and the control circuit is configured to control the first power device and the second power device.

10. The power module of claim 9, further comprising:
a third die arranged on top of the third lead frame, wherein a first control circuit is formed on the third die, and the first control circuit is configured to control the first power device; and
a fourth die arranged on top of the fourth lead frame, wherein a second control circuit is formed on the fourth die, and the second control circuit is configured to control the second power device.

11. The power module of claim 9, wherein the first power device has a first terminal, a second terminal, and a control terminal, and the first terminal of the first power device is coupled to a first pad of the first lead frame and is configured to receive a first voltage;
wherein the second power device has a first terminal, a second terminal, and a control terminal, the first terminal of the second power device is coupled to a first pad of the second lead frame, and the second terminal of the second power device is coupled to a second pad of the second lead frame and is configured to receive a second voltage.

12. The power module of claim 11, wherein the second terminal of the first power device and the first terminal of the second power device are coupled together via the first pad of the second lead frame, and the first pad of the second lead frame is configured to provide a switching voltage.

13. The power module of claim 9, wherein the substrate is disposed on top of the first lead frame and the second lead frame and forms a bridge between the first lead frame and the second lead frame such that the first lead frame, the second lead frame, and the substrate together form a U-shaped structure.

14. The power module of claim 9, wherein the first lead frame includes a first DAP configured to connect the first die, and the first DAP is extended to and arranged below the substrate;
wherein the second lead frame includes a second DAP configured to connect the second die, and the second DAP is extended to and arranged below the substrate.

15. The power module of claim 14, wherein the first lead frame further includes a first exposed pad arranged under the first DAP, and the second lead frame further includes a second exposed pad arranged under the second DAP;
wherein a shortest distance between the first DAP and the second DAP is smaller than a shortest distance between the first exposed pad and the second exposed pad.

16. A power module, comprising:
a first lead frame, including:
a first exposed pad; and
a first DAP arranged on top of the first exposed pad;
a first die arranged on top of the first DAP of the first lead frame, wherein a first power device is formed on the first die;
a second lead frame located adjacent to the first lead frame, wherein the first lead frame and the second lead frame are separated from each other, and the second lead frame includes:
a second exposed pad; and
a second DAP arranged on top of the second exposed pad;
a second die arranged on top of the second DAP of the second lead frame, wherein a second power device is formed on the second die; and
a substrate arranged on top of a part of the first lead frame and a part of the second lead frame;
wherein a distance between the first DAP and the second DAP is smaller than a distance between the first exposed pad and the second exposed pad.

17. The power module of claim 16, further comprising:
a third lead frame arranged on top of the substrate;
a third die arranged on top of the third lead frame, wherein a first control circuit is formed on the third die, and the first control circuit is configured to control the first power device; and
a fourth die arranged on top of the third lead frame, wherein a second control circuit is formed on the fourth die, and the second control circuit is configured to control the second power device.

18. The power module of claim 16, wherein the first power device has a first terminal, a second terminal, and a control terminal, the first terminal of the first power device is coupled to a first pad of the first lead frame and is configured to receive a first voltage;
wherein the second power device has a first terminal, a second terminal, and a control terminal, the first terminal of the second power device is coupled to a first pad of the second lead frame, and the second terminal of the second power device is coupled to a second pad of the second lead frame and is configured to receive a second voltage.

19. The power module of claim 18, wherein the second terminal of the first power device and the first terminal of the second power device are coupled together via the first pad of the second lead frame, and the first pad of the second lead frame is configured to provide a switching voltage.

20. The power module of claim 16, wherein the substrate arranged on top of the first lead frame and the second lead frame forms a bridge between the first lead frame and the second lead frame such that the first lead frame, the second lead frame, and the substrate together form a U-shaped structure.
